(19) United States
(12) Patent Application Publication
(10) Pub. No.: US 2002/0179015 A1
(43) Pub. Date: Dec. 5, 2002

(54) Plasma etching system

(76) Inventors: Franz Laermer, Weil der Stadt (DE); Andreas Schilp, Schwaebisch Gmuend (DE)

Correspondence Address: KENYON & KENYON, ONE BROADWAY, NEW YORK, NY, 10004, US

(21) Appl. No.: 10/031,726

(22) PCT Filed: May 10, 2001
(86) PCT No.: PCT/DE01/01777

(30) Foreign Application Priority Data
May 18, 2000 (DE) 100 24 699.0

(51) Int. Cl. C23C 16/00

(52) U.S. Cl. 118/723 CB; 118/723 FI

(57) ABSTRACT

A plasma etching equipment (5) is proposed for especially anisotropic etching a substrate (13) by the action of a plasma (21). For this purpose, a first, especially inductively coupled plasma-generating device (31) is provided, which has a first means (11) for generating a first high-frequency electromagnetic alternating field, an etching chamber (10) for generating a first plasma (21) from reactive particles by the action of the first high-frequency electromagnetic alternating field upon a first reactive gas with the substrate (13) to be etched, and a first gas supply (22). A second plasma-generating device (32) is preconnected to this first plasma-generating device (31), and it has a second means (20), especially a microwave generator (20), for generating a second high-frequency electromagnetic alternating field, a plasma-generating region (33) for generating a second plasma (18) from reactive particles by the action of the second high-frequency electromagnetic alternating field upon a second reactive gas, and a second gas supply (16). In this connection, the generated second plasma (18) of the first plasma-generating device (31) can be supplied at least partially as first reactive gas via the first gas supply (32).

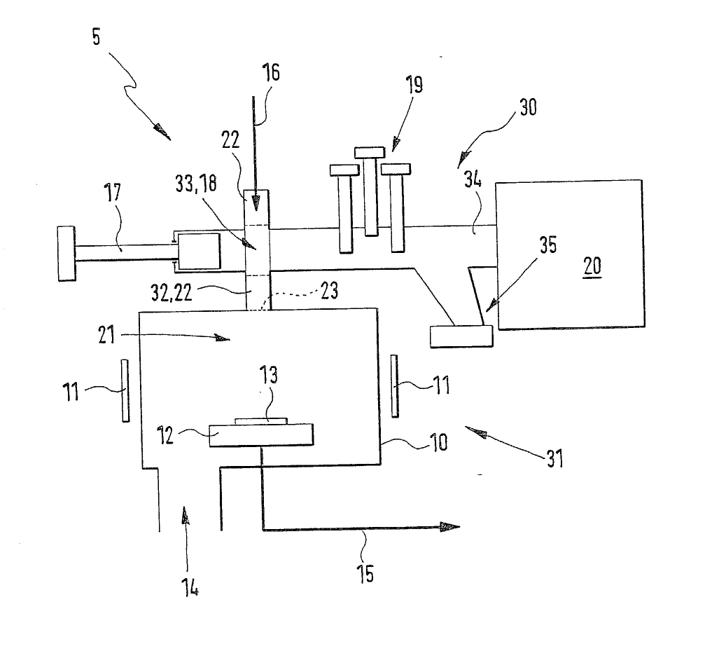

The present invention relates particularly to anisotropic etching of a substrate under the influence of plasma, according to the species defined in the main claim.

### BACKGROUND INFORMATION

Patent DE 42 41 045 C1 describes a high-rate silicon etching process, in which the production of concentrations of fluorine radicals, that are as high as possible, is required for achieving etching rates that are as great as possible. This occurs by irradiation of appropriately high high-frequency wattage into the inductive plasma source applied in the process, having wattage values of typically 3 to 6 kWatt. However, because of such a high wattage, aside from the desired increase of fluorine radical densities, unwanted high densities of ions are also generated, which disturb the etching process and can be harmful to a greatest possible mask selectivity. In addition, such high ion densities also lead in part to unwanted great heating of the substrate to be etched, and cause profile deviations there. That is why, in this known plasma etching equipment, subsequent care, i.e. after the actual plasma generation, has to be taken, by suitable devices, that the ion density is reduced to acceptably low values and is, above all, homogenized, which can be achieved by recombination of ions and electrons along so-called diffusion paths or at aperture constructions. Such an aperture construction is known, for example, from German patent DE 197 34 278 C1. By the use of such aperture constructions, the component of the high frequency power, which was used for generating unwanted high ion densities, is lost in the form of heat or radiation, as the case may be.

Apart from the problems of unwanted high ion density in known plasma etching equipment, the high high-frequency wattages of 3 to 6 kWatt, that are required in this type of equipment, are also problematical and expensive. In particular, such high high-frequency wattages lead to stability problems within the plasma etching equipment, which mostly stem from faulty adaptation of the impedance of the plasma source to the impedance of the plasma generated.

Thus, in response to faulty adaptation of the generated high-frequency wattage to the plasma, damage easily occurs at the applied high-frequency components or high-frequency generators, as the case may be, since, in this case, high electrical voltages or currents arise there, and can develop a destructive effect.

### SUMMARY OF THE INVENTION

Compared to the related art, the plasma etching equipment according to the present invention has the advantage that, when using it, the reactive gases brought in are broken up in great measure, and thus the chemical etching and passivating species required for carrying out the process according to DE 42 41 045 C1 or the process according to DE 197 34 278 C1 are very effectively released. Especially by using the plasma etching equipment according to the present invention, a large quantity of fluorine radicals can be released from the etching gas sulfur hexafluoride, which is preferably used during the etching steps, and during the passivating steps, also a large quantity of teflon-like sidewall polymer-creators (CF₂)ₙ are generated from a passivating gas such as C₄F₈.

In this connection, it is further advantageous that, in the second plasma generating device, only relatively low high-frequency wattages such as 600 to 1200 Watt are required, which presents no problems from an equipment or technical process point of view.

Advantageous further refinements of the present invention result from the measures indicated in the dependent claims.

Thus it is particularly advantageous if the first plasma-creating device is an inductively coupled plasma-creating device, in which there is an ICP source, or rather, an ICP (“inductively coupled plasma”) coil, outside the etching chamber. This inductively coupled plasma-creating device is further especially advantageously connected with a preconnected plasma-creating device in the form of a microwave plasma-creating device. It is achieved thereby, that these devices are connected in the sense of a so-called “downstream” arrangement, the reactive gases brought in flowing, directly before the inductively coupled plasma-creating device, through a dielectric pipe such as a quartz pipe or a ceramic pipe, in which a highly dense plasma is maintained in a relatively small volume by intensive microwave irradiation. Thus the reactive gases brought in are already broken down in great measure by this microwave plasma, and the etching species and passivating species required for the etching steps and passivating steps, respectively, are released.

In this connection, it is further advantageous that the ions, unavoidably also generated at a relatively high density in the microwave plasma, can be first rendered harmless, before conveying this plasma as reactive gas into the plasma of the inductively coupled plasma-creating device, by the microwave plasma-creating device having either a sufficient distance from the actual etching chamber having the inductively coupled plasma-creating device, so that the unwanted high ion density in this microwave plasma is reduced again by volume recombinations or wall recombinations, as the case may be, or, preferably, or by placing a discharge device near the entrance to the gas inlet to the first plasma-creating device, i.e. at the transition of the microwave plasma into the etching chamber having the inductively coupled plasma-creating device.

Preferably, this discharge device is a metallic or ceramic grid, a perforated plate or perforated sheet metal, as the case may be, or a so-called showerhead at which ions derived from the microwave plasma are completely discharged or recombined with electrons while passing through. Here, use is made of the fact that such a discharge device acts completely neutral toward neutral fluorine radicals or polymer-forming monomers. Besides that, an additional heating device, or rather, heating of the discharge device will ensure that no unwanted deposition of reactive gases or reaction products of the reactive gases takes place on this discharge device. Such heating, after all, can take place passively, since heating, that is indeed several times more than enough, is a given on account of the heating input of the microwave plasma located above.

The use of a discharge device especially in the form of a metallic grid or perforated sheet metal further prevents microwave radiations from passing over from the microwave plasma-generating device into the inductively coupled plasma-generating device, so that, at that point, an otherwise considerable effort in safety technology, for the purpose of shielding from these radiations, can be avoided.

All in all, by using the discharge device, one can thus advantageously achieve that only neutral radicals for etching or sidewall passivating are conveyed in, while charged particles are at least extensively neutralized before entering the etching chamber, and furthermore, also microwave radiation is blocked at the entrance to the etching chamber.

It is particularly cost-effective to use microwave radiation, or rather, a microwave generator in the preconnected second plasma-generating device since, thanks to the advanced technology of microwave heating apparatus, power in the kWatt range can be produced at extraordinarily favorable prices. For this, mostly so-called magnetron tubes are used. Besides that, in the case of microwave activation, there is not the risk of the destruction of especially electronic components in the case of a faulty adaptation, since reflected microwave power in the cavity resonator used, and known per se, can be conducted or carried off to a so-called water load, i.e. an absorber of microwave radiation. Thus it is possible to work with extremely high powers, such as 5 to 10 kWatt in the preconnected second plasma-generating device, and to make available extremely high densities of neutral radicals to the actual post-connected etching chamber. Since fluorine radicals and the monomers building up the sidewall passivation have a relatively long life for a process according to DE 42 41 045 C1 and therefore have great reach, losses of such species up to the point of the actual etching reaction, i.e. at the substrate, are negligibly small.

The method performed according to DE 42 41 045 C1 is usually operated on inductively coupled plasma etching equipment using an oxygen proportion of 5% to 10% of the flow of sulfur hexafluoride as etching gas in the etching steps, in order thereby to suppress harmful sulfur separation in the exhaust gas region of the equipment. The oxygen proportion, which, by the way, must only be added during the etching steps, has up to this point no further effect on the etching result, since reactive gas sulfur hexafluoride is reduced only to stable sulfur tetrafluoride (SF4) under the ICP activating conditions, with the release of fluorine radicals, and, at the relatively low excitation densities in inductively coupled plasma-generating devices, only a small part is broken down to low sulfur-fluorine compounds capable of reacting with oxygen. That is why, in the plasma equipment known so far, the increase in fluorine radical concentration in the plasma by saturation of such low sulfur fluorine compounds with oxygen, with further release of fluorine, is negligible, so that the addition of oxygen does not have an increasing etching rate effect up to this point. In contrast, by the use of a microwave plasma-generating device, in which extremely high power concentrations are generated in a very small volume, by adding oxygen it is advantageously achieved, at this point, that such reactions of sulfur-fluorine compounds with oxygen radicals appear in considerable measure, and thereby make available additional fluorine radicals. Thus, in the case of the plasma etching equipment according to the present invention, the addition of oxygen is no longer neutral with respect to the fluorine radical density generated in the etching chamber, but it effects a significant increase in available fluorine radical quantities and thereby permits higher etching rates for silicon.

The first plasma-generating device, having the actual etching chamber with inductive plasma excitation, connected following the second plasma-generating device, thus has, first of all, the task of bringing about controlled ionization of the reactive gas brought in, composed of essentially neutral radicals and still unused reactive gases. Now, for this purpose, relatively low high frequency powers such as 600 to 1200 Watt are advantageously sufficient. Besides generating the ion concentrations required for an anisotropic etching process, the first plasma-generating device is now used further for the second purpose of also generating etching species or, to a small extent, passivating species. In this regard, inductive plasma excitation, as opposed to microwave excitation, in the actual etching chamber has the advantage that, with the aid of suitable devices installed in the etching chamber, in particular aperture plates, especially uniform etching results are achieved over the entire surface of the substrate to be etched.

### BRIEF DESCRIPTION OF THE DRAWINGS

The present invention is explained in greater detail on the basis of the drawing and the following description. The FIGURE shows a block diagram of a plasma etching equipment in cross section.

### EXEMPLARY EMBODIMENTS

The present invention is initially directed at an anisotropic etching procedure for etching silicon with the aid of a plasma, as is known, for example, from DE 42 41 045 C1. Here, passivating steps and etching steps are applied alternatingly, a mixture of sulfur hexafluoride and argon being used as reactive gas during the etching steps, to which oxygen is additionally admixed. During the passivating steps, a gaseous fluorocarbon or fluorohydrocarbon is used, such as C4F8 or CHF3 is used, if necessary, mixed with argon. With respect to further details on this process known per se, we refer to DE 42 41 045 C1. Detailed information on the concrete execution of the process, especially with regard to the gases and gas flows that can be used, may further be inferred also from DE 198 26 382 A1.

Furthermore, the plasma etching equipment according to the present invention starts in the first place from a first plasma-generating device 31, as is known from German Patent DE 197 34 278 C1. This plasma-generating device 31 is modified, according to the present invention, in that a second plasma-generating device 30 is preconnected to it.

The FIGURE first of all shows first plasma-generating device 31, known in principle from DE 197 34 278 C1, which is connected to second plasma-generating device 30 in the area of a discharge device 23. The first plasma-generating device 31 also has an etching chamber 10, to which a reactive gas or a reactive gas mixture can be supplied with the aid of a first gas inlet 32 in the form of a dielectric pipe 22. It is further provided that first plasma-generating device 31 is furnished with a second plasma source 11. The second plasma source 11 is, in the example explained, an ICP coil having an appertaining high frequency generator component, with which a high frequency electromagnetic alternating field can be generated inside the etching chamber, which, by acting upon reactive particles made available by the first reactive gas, generates a first gas plasma 21 inside etching chamber 10 or which, by coupling in the high frequency magnetic field generated by ICP coil 11 in etching chamber 10, charged with reactive gas, leads to triggering of first gas plasma 21.

Furthermore, in etching chamber 10 a substrate 13, such as a silicon wafer, is provided, which is electrically connected to a substrate electrode 12, which is itself connected to a high frequency voltage source (not shown) by a line 15. Thus, the application of a high frequency a.c. voltage to substrate electrode 12 has the effect of speeding up the ions contained in first gas plasma 21 in the direction of substrate 13, which, in a known way, leads to anisotropic etching of silicon, for instance.

Furthermore, an aperture or an aperture having a cylindrical upper part can be provided inside etching chamber 10, as is described in detail in DE 197 34 278 C1. Beyond that, the efficiency of plasma generation in etching chamber 10 can be still further increased by the second plasma source 11 by an additional magnetic field. A device suitable for this is described in German Application DE 199 33 841.8.

Besides that, first plasma-generating device 31 is also connected to an exhaust pipe 14 and a controlling valve, so that, with it, a specified pressure can be set inside etching chamber 10.

Preconnected to first plasma-generating device 31 is second plasma-generating device 30, which is designed in the form of a microwave plasma-generating device. For this purpose, second plasma-generating device 30 has a microwave generator 20, which is designed especially in the form of a magnetron or a magnetron tube. This supplies, for example, a microwave power of 5 to 15 kWatt at a frequency of 2.45 GHz. The microwave power generated by microwave generator 20 is then further coupled into a cavity resonator 34, which is equipped with a tuning device 17 known per se for tuning its cavity length. Tuning device 17 is used for tuning the resonant frequency of cavity resonator 34 with the microwave radiation emitted by microwave generator 20.

It is also provided that cavity resonator 34 have an adaptation device 19 known per se, for adapting the mode of the coupled microwave radiation to a generated microwave plasma. Using this, a circular mode is set in cavity resonator 34, which, in view of the shape of its mode, can well be adapted to the usually rotationally symmetrical microwave plasma.

Finally, a directional coupler 35 ensures that, microwave power reflected in unwanted fashion, appearing as a result of, for instance, a temporarily faulty adaptation of the resonant frequency of cavity resonator 34 to the irradiated microwaves in cavity resonator 34, can be at least partially dissipated. For this purpose, cavity resonator 34 preferably has a plurality of such directional couplers 35, known per se, which, on their part, are directed toward a so-called “water load”, where the microwave power dissipated via directional coupler(s) 35 from cavity resonator 34 can be converted in a harmless manner into heat. In this respect, instead of a water load, alternatively another type of absorber of microwave radiation can be used.

Second plasma-generating device 30 also has at least one gas inlet 16, via which the reactive gases or reactive gas mixtures, known from DE 42 41 045 C1, that are to be conveyed to second plasma-generating device 30, are introduced. In the explained exemplary embodiment it is provided that this second gas inlet 16 is executed at least in the direct surroundings of cavity resonator 34, in the form of a dielectric tube 22, such as a quartz tube or a ceramic tube, which penetrates cavity resonator 34. In this respect, a plasma-generating region 33 forms in cavity resonator 34 inside tube 22, in which a microwave plasma is triggered by supplying a reactive gas through second gas inlet 16. This microwave plasma has an especially high power density, such as 30 to 100 Watt/cm³ at a typically low volume of only 10 cm³ to 200 cm³.

In the explained exemplary embodiment it is further provided that plasma-generating region 33 is located within tube 22 in an area of the connection of the first plasma-generating device 31 to second plasma-generating device 32. It is particularly provided that dielectric tube 22 is formed as a dielectric tube crossing some portions of cavity resonator 34 and leading into etching chamber 10, so that second plasma 18, generated in plasma-generating region 33 can be conveyed from first plasma-generating device 31, via first gas inlet 32, at least partially as first reactive gas to etching chamber 10. Therein, then, using the reactive gas thus supplied, first gas plasma 21 is triggered by the explained inductively coupled plasma activation.

In the region of the transition of dielectric tube 22 or first gas inlet 32 from second plasma-generating device 30 to first plasma-generating device 31, a discharge device 23 is additionally provided, which effects an at least partial discharge of ions and/or electrons from second plasma 18. This discharge device 23 is designed, for example, in the form of a metallic or ceramic grid, a perforated plate or a showerhead, which leads to ions stemming from second gas plasma 18 being neutralized or recombined with electrons when passing through discharge device 23. At the same time, discharge device 23 is permeable, for example, to neutral fluorine radicals or polymer-forming monomers.

In one preferred specific embodiment it is further provided that discharge device 23 is furnished with a heating device (not shown), so that deposition of reactive gases or reactive gas products on discharge device 23 can be suppressed. If it is made of metal, discharge device 23 also has the effect of shielding microwave radiation coming from cavity resonator 34 from etching chamber 10, so that the latter cannot overflow into first plasma-generating device 31.

Thus, all in all, the plasma etching equipment 5 explained is designed in the form of a so-called downstream arrangement having a preconnected microwave plasma-generating device and a post-connected, inductively coupled plasma-generating device. In this connection, the reactive gases supplied, directly before entering inductively coupled plasma-generating device 31, flow through cavity resonator 34, where a second gas plasma 18 is triggered or maintained. Thus, by a combination of a microwave plasma source known per se, in connection with an “ion neutralizer”, in the form of discharge device 23 for generating an essentially ion-free radical mixture from a supplied reactive gas, and a post-connected, inductively coupled plasma-generating device in the sense of a hybrid set-up, extremely high etching rates can be achieved, for instance, during etching of silicon, without the otherwise appearing harmful side effects, such as heating of the substrate, loss of selectivity or profile disturbances.

In this connection, the breakup of a big part of the reactive gas species before the actual etching chamber 10, using microwave excitation, represents an especially efficient and cost-effective variant for obtaining a high density of etching species and also passivating species.

It should also be emphasized in this connection that commercially obtainable, inductively coupled plasma-generating devices 31 can be upgraded retroactively, in a simple manner, using an additional second plasma-generating device in the form of a microwave plasma-generating device.

What is claimed is:

1. A plasma etching equipment for especially anisotropic etching of a substrate by the action of a plasma, having a first plasma-generating device which has a first means for generating a first high-frequency electromagnetic alternating field, an etching chamber for generating a first plasma of reactive particles by the action of the first high-frequency electromagnetic alternating field upon a first reactive gas, and a first gas supply; the substrate to be etched being positioned in the etching chamber, wherein a second plasma-generating device (32) is preconnected to a first plasma-generating device (31) and has a second means (20) for generating a second high-frequency electromagnetic alternating field, a plasma-generating region (33) for generating a second plasma (18) from reactive particles by the action of the second high-frequency electromagnetic alternating field upon a second reactive gas, and a second gas supply (16); the second plasma (18) being able to be supplied at least partially, as the first reactive gas, to the first plasma-generating device (31) via the first gas supply (32).

2. The plasma etching equipment as recited in claim 1, wherein the first plasma-generating device (31) is an inductively coupled plasma-generating device, which has as the first means at least one ICP coil (11).

3. The plasma etching equipment as recited in claim 1, wherein the first plasma-generating device (31) has a substrate electrode (12), connected to a high-frequency voltage source by a supply line (15), with which an ion stream contained in the first plasma (21) can be accelerated onto the substrate (13).

4. The plasma etching equipment as recited in claim 1, wherein the second means (20) is a microwave generator (20), especially a magnetron or a magnetron tube, and the second plasma-generating device (32) is a microwave plasma-generating device.

5. The plasma etching equipment as recited in claim 1 or 4, wherein the second plasma-generating device (32) has a cavity resonator (34).

6. The plasma etching equipment as recited in claim 5, wherein the cavity resonator (34) has a tuning device (17) for tuning the resonant frequency of the cavity resonator (34).

7. The plasma etching equipment as recited in claim 5 or 6, wherein the cavity resonator (34) has an adaptation device (19) for adapting a microwave mode generated by the microwave plasma-generating device to the second plasma (18).

8. The plasma etching equipment as recited in claim 7, wherein the microwave plasma-generating device has at least one directional coupler (35) and is in contact with an absorber of microwave radiation, in particular a water load.

9. The plasma etching equipment as recited in at least one of the preceding claims, wherein the first plasma-generating device (31) and the second plasma-generating device (32) are connected to each other, open to the passage of gas, via a dielectric tube (22), especially a quartz tube or a ceramic tube, the dielectric tube (22) being in contact with the first gas supply (32) and the second gas supply (16) in a manner open to the passage of gas.

10. The plasma etching equipment as recited in at least one of the preceding claims, wherein the plasma-generating region (33) is located inside the cavity resonator (34) in surroundings of the connection of the first plasma-generating device (31) to the second plasma-generating device (32) on the inside of the dielectric tube (22) which crosses the cavity resonator in some regions.

11. The plasma etching equipment as recited in at least one of the preceding claims, wherein the dielectric tube (22) forms the second gas supply (16).

12. The plasma etching equipment as recited in at least one of the preceding claims, wherein, between the first plasma-generating device (31) and the second plasma-generating device (32), a discharge device (23) is provided which has the effect of at least partially discharging ions and/or electrons from the second plasma (18).

13. The plasma etching equipment as recited in at least one of the preceding claims, wherein the discharge device (23) can be heated.

14. The plasma etching equipment as recited in at least one of the preceding claims, wherein the discharge device (23) is positioned inside the dielectric tube (22) and/or near the entrance of the first gas supply (32) into the first plasma-generating device (31).

15. The plasma etching equipment as recited in at least one of the preceding claims, wherein the discharge device (23) is a metallic or ceramic grid, a perforated plate or a showerhead.

16. The plasma etching equipment as recited in at least one of the preceding claims, wherein the discharge device (23) is positioned between the first plasma-generating device (31) and the second plasma-generating device (32) in such a way that the first reactive gas which can be supplied to the first plasma-generating device (31) via the first gas supply (32) passes through at least almost completely through the discharge device (23).
